(19) United States
(12) Patent Application Publication
(10) Pub. No.: US 2026/0253631 A1
(43) Pub. Date: Aug. 27, 2026

(54) MEMORY DEVICE CONFIGURED TO INPUT AND OUTPUT DATA

(71) Applicant: SK hynix Inc., Icheon-si Gyeonggi-do (KR)

(72) Inventors: Su Hyun OH, Icheon-si Gyeonggi-do (KR); Young Jun PARK, Icheon-si Gyeonggi-do (KR)

(73) Assignee: SK hynix Inc., Icheon-si Gyeonggi-do (KR)

(21) Appl. No.: 19/243,288

(22) Filed: Jun. 19, 2025

(30) Foreign Application Priority Data
Feb. 26, 2025 (KR) 10-2025-0025394

(51) Int. Cl. G11C 11/4076; H10B 80/00; H10W 90/00; H10W 90/20

(52) U.S. Cl. CPC G11C 11/4076; H10B 80/00; H10W 90/00; H10W 90/291; H10W 90/297; H10W 90/722; H10W 90/724

(57) ABSTRACT

A memory device includes a base chip configured to generate a plurality of division clocks each having a first frequency by dividing the frequencies of an even read signal and an odd read signal generated based on a read command, configured to generate first and second output strobe signals each having a second frequency by synthesizing the plurality of division clocks, and configured to output the first and second output strobe signals through signal paths, and a core chip vertically stacked on the base chip and configured to output data to the base chip in synchronization with the first and second output strobe signals.

### CROSS-REFERENCE TO RELATED APPLICATION

The present application claims priority under 35 U.S.C. §119(a) to Korean Patent Application No. 10-2025-0025394, filed in the Korean Intellectual Property Office on February 26, 2025, the entire contents of which application is incorporated herein by reference.

### BACKGROUND

The present disclosure generally relates to a memory device, and more particularly, to a memory device configured to input and output data by providing a plurality of core chips with a strobe signal generated by a base chip.

As a technology for manufacturing a semiconductor device is developed, a packaging technology for a plurality of core chips for implementing the semiconductor device accomplishes high integration and high performance. In packaging technologies for implementing the semiconductor device, a technology relating to a three-dimensional structure in which a plurality of core chips is vertically stacked out of the two-dimensional structure in which a plurality of core chips is flatly disposed on a printed circuit board (PCB) is variously developed. The semiconductor device having the three-dimensional structure may be implemented by stacking a plurality of core chips through a through silicon via (TSV) (hereinafter referred to as a “through via”), like high bandwidth memory (HBM), or may be implemented by stacking a plurality of core chips through wire bonding.

In general, access to a core chip may be performed through a base chip. For example, after the start of read for the core chip, the base chip may transmit a strobe signal that strobes a read command and data to the core chip. The core chip may output data to the base chip in synchronization with the strobe signal.

### SUMMARY

In an embodiment, a memory device may include a base chip configured to generate a plurality of division clocks each having a first frequency by dividing the frequencies of an even read signal and an odd read signal generated based on a read command, configured to generate first and second output strobe signals each having a second frequency by synthesizing the plurality of division clocks, and configured to output the first and second output strobe signals through a first signal path and second signal path, respectively, and a core chip vertically stacked on the base chip through a portion of the first and second signal paths located between the core chip and the base chip, the core chip spaced apart from the base chip with the portions of the first and second signal paths, and the core chip configured to output data to the base chip through a third signal path and a fourth signal path in synchronization with the first and second output strobe signals.

In an embodiment, a memory device may include a base chip configured to generate an even read signal that is generated based on a first read command and an odd read signal that is generated based on a second read command, configured to generate first to third division clocks each having a first frequency by dividing the frequency of the even read signal, configured to generate fourth to sixth division clocks each having the first frequency by dividing the frequency of the odd read signal, configured to generate a first output strobe signal having the second frequency by synthesizing the first to third division clocks, and configured to generate a second output strobe signal having the second frequency by synthesizing the fourth to sixth division clocks, a first core chip configured to output first data to the base chip in synchronization with the first and second output strobe signals, and a second core chip configured to output second data to the base chip in synchronization with the first and second output strobe signals.

### BRIEF DESCRIPTION OF THE DRAWINGS

FIG. 1 is a block diagram illustrating a construction of a memory system according to an embodiment of the present disclosure.

FIG. 2 is a block diagram illustrating a construction of a memory device according to an embodiment of the present disclosure.

FIG. 3 is a block diagram illustrating a construction of a base chip according to an embodiment of the present disclosure.

FIG. 4 is a block diagram illustrating a construction of a read control circuit according to an embodiment of the present disclosure.

FIG. 5 is a block diagram illustrating a construction of a shifting circuit according to an embodiment of the present disclosure.

FIG. 6 is a diagram illustrating a construction of a read signal generation circuit according to an embodiment of the present disclosure.

FIG. 7 is a block diagram illustrating a construction of a base strobe signal generation circuit according to an embodiment of the present disclosure.

FIG. 8 is a block diagram illustrating a construction of a signal synthesis circuit according to an embodiment of the present disclosure.

FIG. 9 is a block diagram illustrating a construction of a synchronization circuit according to an embodiment of the present disclosure.

FIG. 10 is a circuit diagram illustrating a construction of a strobe signal generation circuit according to an embodiment of the present disclosure.

FIG. 11 is a block diagram illustrating a construction of a data input and output circuit according to an embodiment of the present disclosure.

FIG. 12 is a block diagram illustrating a construction of a first memory circuit according to an embodiment of the present disclosure.

FIGS. 13 to 15 are timing diagrams for describing read operations of the memory device according to an embodiment of the present disclosure.

FIG. 16 is a diagram for describing location at which a peripheral region, an interface region, and a through via region included in the base chip are disposed according to an embodiment of the present disclosure.

### DETAILED DESCRIPTION

In the descriptions of the following embodiments, the term "preset" indicates that the numerical value of a parameter is previously decided, when the parameter is used in a process or algorithm. According to an embodiment, the numerical value of the parameter may be set when the process or algorithm is started or while the process or algorithm is performed.

Terms such as "first" and "second," which are used to distinguish among various components, are not limited by the components. For example, a first component may be referred to as a second component, and vice versa.

When one component is referred to as being "coupled" or "connected" to another component, it should be understood that the components may be directly coupled or connected to each other or coupled or connected to each other through another component interposed therebetween. In contrast, when one component is referred to as being "directly coupled" or "directly connected" to another component, it should be understood that the components are directly coupled or connected to each other without another component interposed therebetween.

A "logic high level" and a "logic low level" are used to describe the logic levels of signals. A signal having a "logic high level" is distinguished from a signal having a "logic low level." For example, when a signal having a first voltage corresponds to a signal having a "logic high level," a signal having a second voltage may correspond to a signal having a "logic low level." According to an embodiment, a "logic high level" may be set to a voltage higher than a "logic low level." According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

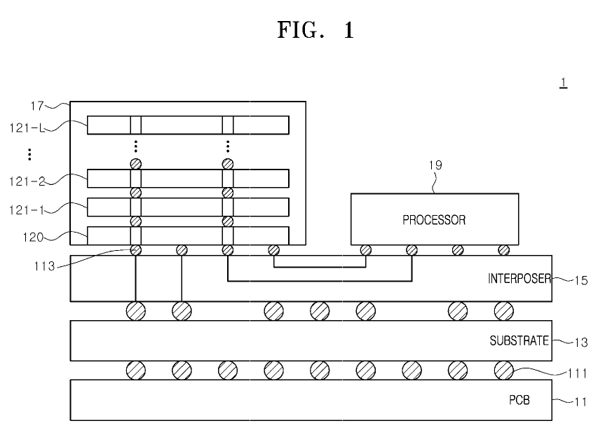

FIG. 1 is a block diagram illustrating a construction of a memory system 1 according to an embodiment of the present disclosure. As illustrated in FIG. 1, the memory system 1 may include a PCB 11, a substrate 13, an interposer 15, a memory device 17, and a processor 19.

The PCB 11 connects several electronic parts in order to form an electronic circuit (not illustrated). A copper layer, a solder mask, and a silk screen may be formed in the PCB 11. A circuit path along which a signal or power is transmitted may be formed in the copper layer. The solder mask prevents or mitigates damage to the circuit and protects a specific region in which a part may be soldered. Furthermore, the silk screen displays the locations of electronic parts or information in the form of letters or symbols printed on a surface of the PCB 11.

The substrate 13 is formed over the PCB 11 through bump pads, for example, 111, and may mechanically support the interposer 15, the memory device 17, and the processor 19. The substrate 13 may be usually used as an insulator as a material that is a physical base of the PCB 11. Materials of the substrate 13 include flame retardant 4 (FR4) that is an insulator made of glass fiber and epoxy resin, ceramic that is mainly used in a high frequency circuit or a high temperature environment because the ceramic can withstand a high temperature and has excellent thermal conductivity, and polyimide that is used as a basic material of a flexible PCB due to a flexible characteristic.

The interposer 15 is formed over the substrate 13 through bump pads, and may include electronic parts having form factors or pin arrangements not matched, for example, wires that connect the memory device 17 and the processor 19. The interposer 15 may convert signals at different interfaces.

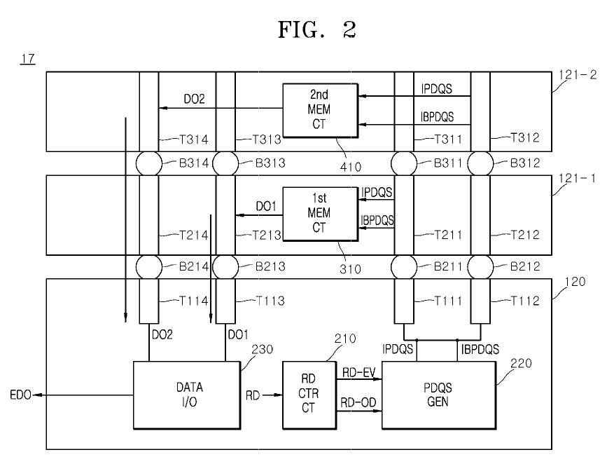

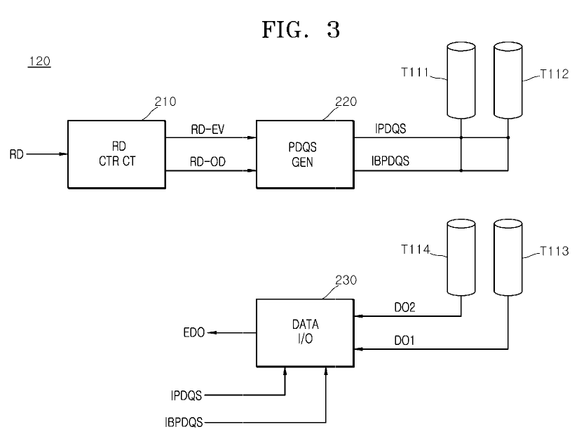

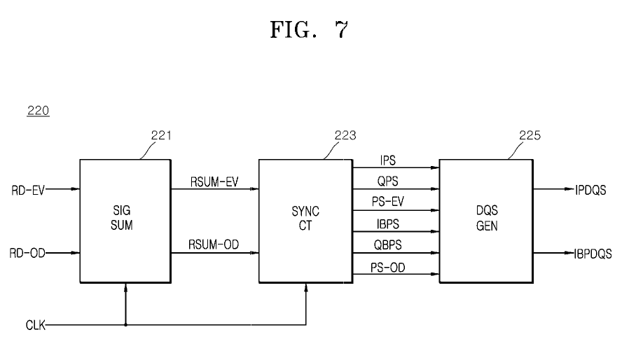

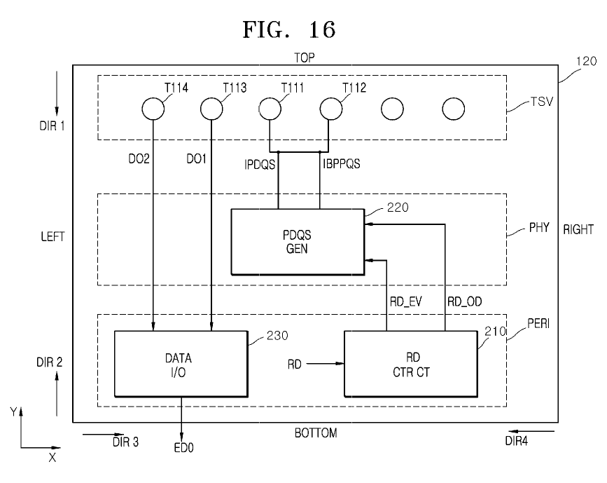

The memory device 17 may be formed over the interposer 15 through micro bumps, for example, 113. The memory device 17 may store data applied by the processor 19 or may output stored data to the processor 19 under the control of the processor 19. The memory device 17 may include a base chip 120 and a plurality of core chips 121-1 to 121-L. The plurality of core chips 121-1 to 121-L may be vertically stacked over the base chip 120 through micro bumps. In an embodiment, the core chips may be vertically stacked on each other through micro bumps as shown in FIG. 2. Additionally, the core chip closest to the base chip 120 may be vertically stacked on the base chip through micro bumps as shown in FIG. 2. The base chip 120 and the plurality of core chips 121-1 to 121-L may be vertically connected through through vias. In an embodiment, the base chip 120 and the plurality of core chips 121-1 to 121-L may be vertically connected through through vias and the micro bumps. In an embodiment, the core chip 121-1 is vertically stacked on the base chip 120 through a portion of the first and second signal paths (e.g., first and second signal paths) (e.g., first micro bump B211 and second micro bump B212) located between the core chip 121-1 and the based chip 120. In an embodiment, the first core chip 121-1 is spaced apart from the base chip 120 with the portions of the first and second signal paths (e.g., first micro bump B211 and second micro bump B212). The core chip may be configured to output data to the base chip through the third and fourth signal paths in synchronization with the first and second output strobe signals. In an embodiment, the first core chip 121-1 is spaced apart from the base chip 120 with the portions of the third and fourth signal paths (e.g., third micro bump B213 and fourth micro bump B214). The base chip 120 may generate a plurality of division clocks (IPS, QPS, PS-EV, IBPS, QBPS, and PS-OD in FIG. 7) each having a first frequency by dividing the frequencies of an even read signal (RD-EV in FIG. 2) and an odd read signal (RD-OD in FIG. 2) that are generated based on a read command (RD in FIG. 2) that performs a read operation. The base chip 120 may generate the plurality of division clocks (IPS, QPS, PS-EV, IBPS, QBPS, and PS-OD in FIG. 7) each having the first frequency by dividing the frequencies of the even read signal (RD-EV in FIG. 2) and the odd read signal (RD-OD in FIG. 2) in an interface region (PHY in FIG. 16) having long loading. The base chip 120 may generate first and second output strobe signals (IPDQS and IBPDQS in FIG. 2) each having a second frequency by synthesizing the plurality of division clocks (IPS, QPS, PS-EV, IBPS, QBPS, and PS-OD in FIG. 7). The base chip 120 may generate the first and second output strobe signals (IPDQS and IBPDQS in FIG. 2) each having the second frequency by synthesizing the plurality of division clocks (IPS, QPS, PS-EV, IBPS, QBPS, and PS-OD in FIG. 7) in a TSV region (TSV in FIG. 16) having shorter loading than the interface region (PHY in FIG. 16). The base chip 120 may output the first and second output strobe signals (IPDQS and IBPDQS in FIG. 2) to the plurality of core chips 121-1 to 121-L through a signal path. The base chip 120 may receive data (DO1 and DO2 in FIG. 2) from the plurality of core chips 121-1 to 121-L through the signal path. The base chip 120 may generate external data (EDO in FIG. 3) from the data (DO1 and DO2 in FIG. 2) in synchronization with the first and second output strobe signals (IPDQS and IBPDQS in FIG. 2). The base chip 120 may output the external data (EDO in FIG. 3) to the processor 19 through the wires of the interposer 15. The signal path may be set as a path along which the micro bumps and the through vias are connected. Long loading may refer to a path, along which a signal is transmitted, including a wire that has a relatively longer length than another wire. For example, the loading of the interface region (PHY in FIG. 16) may be set to have a longer loading than the loading for the TSV region (TSV in FIG. 16).

Each of the plurality of core chips 121-1 to 121-L may include a memory circuit that stores data and outputs stored data. Each of the plurality of core chips 121-1 to 121-L may include a plurality of channel regions that independently operates. Each of the plurality of channel regions may be assigned a channel that independently operates, and may receive or transmit data. Each of the plurality of channel regions includes a core region, and may receive or transmit data. The number L of core chips 121-1 to 121-L may be 4, 8, 12, or 16. For example, when each of the core chips 121-1 to 121-12 has eight channels, each of the core chips 121-1 to 121-4, the core chips 121-5 to 121-8, and the core chips 121-9 to 121-12 includes 32 channel regions, and may transmit and receive data to and from the processor 19 in a rank unit including thirty-two channels.

The processor 19 may control the base chip 120 through the wires formed within the interposer 15.

FIG. 2 is a block diagram illustrating a construction of the memory device 17 according to an embodiment of the present disclosure. As illustrated in FIG. 2, the memory device 17 may include the base chip 120, the first core chip 121-1, and the second core chip 121-2.

The base chip 120 may include a first through via T111, a second through via T112, a third through via T113, a fourth through via T114, a read control circuit (RD CTR CT) 210, a base strobe signal generation circuit (PDQS GEN) 220, and a data input and output circuit (DATA I/O) 230.

The first through via T111 may be electrically connected to a first micro bump B211. The second through via T112 may be electrically connected to a second micro bump B212. The third through via T113 may be electrically connected to a third micro bump B213. The fourth through via T114 may be electrically connected to a fourth micro bump B214. The first through via T111, the second through via T112, the third through via T113, and the fourth through via T114 may each be set as a common through via that penetrates the base chip 120. The first micro bump B211, the second micro bump B212, the third micro bump B213, and the fourth micro bump B214 may each be set as a common micro bump that is disposed on the base chip 120 and under the first core chip 121-1.

The read control circuit 210 may be disposed in a peripheral region (PERI in FIG. 16). The read control circuit 210 may generate the even read signal RD-EV and the odd read signal RD-OD that are generated when the read command RD is input. The read control circuit 210 may generate the even read signal RD-EV that is generated when a first read command RD is input. The read control circuit 210 may generate the odd read signal RD-OD that is generated when a second read command RD is input. The first read command RD and the second read command RD may be set as the read commands RD that are continuously input.

The base strobe signal generation circuit 220 may be disposed in the interface region (PHY in FIG. 16). The base strobe signal generation circuit 220 may generate the plurality of division clocks (IPS, QPS, PS-EV, IBPS, QBPS, and PS-OD in FIG. 7) each having the first frequency by dividing the frequencies of the even read signal RD-EV and the odd read signal RD-OD. The base strobe signal generation circuit 220 may generate the first output strobe signal IPDQS and the second output strobe signal IBPDQS each having the second frequency by synthesizing the plurality of division clocks (IPS, QPS, PS-EV, IBPS, QBPS, and PS-OD in FIG. 7). The base strobe signal generation circuit 220 may output the first output strobe signal IPDQS and the second output strobe signal IBPDQS to the first core chip 121-1 through the first through via T111 and the first micro bump B211. The base strobe signal generation circuit 220 may output the first output strobe signal IPDQS and the second output strobe signal IBPDQS to the first core chip 121-1 through a first signal path. The base strobe signal generation circuit 220 may output the first output strobe signal IPDQS and the second output strobe signal IBPDQS to the second core chip 121-2 through the second through via T112 and the second micro bump B212. The base strobe signal generation circuit 220 may output the first output strobe signal IPDQS and the second output strobe signal IBPDQS to the first core chip 121-2 through a second signal path. The first signal path may be set as a path including the first through via T111, the first micro bump B211, the fifth through via T211 of the first core chip 121-1, the fifth micro bump B311, and the ninth through via T311 of the second core chip 121-2. The second signal path may be set as a path including the second through via T112, the second micro bump B212, the sixth through via T212 of the first core chip 121-1, the sixth micro bump B312, and the tenth through via T312 of the second core chip 121-2.

The data input and output circuit 230 may be disposed in the interface region (PHY in FIG. 16). The data input and output circuit 230 may receive the first data DO1 from the first core chip 121-1 through the third through via T113. The data input and output circuit 230 may output the first data DO1 as the external data EDO. The data input and output circuit 230 may receive second data DO2 from the second core chip 121-2 through the fourth through via T114. The data input and output circuit 230 may output the second data DO2 as the external data EDO.

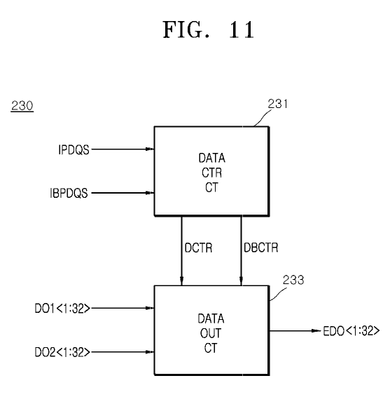

The base chip 120 may receive the first data DO1 from the first core chip 121-1 through the third through via T113 and the third micro bump B213, and may output the first data DO1 as the external data EDO. The base chip 120 may receive the first data DO1 from the first core chip 121-1 through a third signal path, and may output the first data DO1 as the external data EDO. The base chip 120 may receive the second data DO2 from the second core chip 121-2 through the fourth through via T114 and the fourth micro bump B214, and may output the second data DO2 as the external data EDO. The base chip 120 may receive the second data DO2 from the second core chip 121-2 through a fourth signal path, and may output the second data DO2 as the external data EDO. The third signal path may be set as a path including the third through via T113, the third micro bump B213, the seventh through via T213 of the first core chip 121-1, the seventh micro bump B313, and the eleventh through via T313 of the second core chip 121-2. The fourth signal path may be set as a path including the fourth through via T114, the fourth micro bump B214, the eighth through via T214 of the first core chip 121-1, the eighth micro bump B314, and the twelfth through via T314 of the second core chip 121-2. An operation of the base chip 120 receiving the first data DO1 and the second data DO2 and outputting the first data DO1 and the second data DO2 as the external data EDO is described in detail later with reference to FIGS. 3 and 11.

The first core chip 121-1 may include a fifth through via T211, a sixth through via T212, a seventh through via T213, an eighth through via T214, and a first memory circuit (1^{st} MEM CT) 310.

The fifth through via T211 may be electrically connected to the first micro bump B211 and a fifth micro bump B311. The sixth through via T212 may be electrically connected to the second micro bump B212 and a sixth micro bump B312. The seventh through via T213 may be electrically connected to the third micro bump B213 and a seventh micro bump B313. The eighth through via T214 may be electrically connected to the fourth micro bump B214 and an eighth micro bump B314. The fifth through via T211, the sixth through via T212, the seventh through via T213, and the eighth through via T214 may each be set as a common through via that penetrates the first core chip 121-1. The fifth micro bump B311, the sixth micro bump B312, the seventh micro bump B313, and the eighth micro bump B314 may each be set as a common micro bump that is disposed on the first core chip 121-1 and under the second core chip 121-2.

The first memory circuit 310 may receive the first output strobe signal IPDQS and the second output strobe signal IBPDQS through the fifth through via T211. The first memory circuit 310 may receive the first output strobe signal IPDQS and the second output strobe signal IBPDQS through the first signal path. The first memory circuit 310 may output the first data DO1 to the base chip 120 through the seventh through via T213 in synchronization with the first output strobe signal IPDQS and the second output strobe signal IBPDQS. The first memory circuit 310 may output the first data DO1 to the base chip 120 through the third signal path in synchronization with the first output strobe signal IPDQS and the second output strobe signal IBPDQS.

The second core chip 121-2 may include a ninth through via T311, a tenth through via T312, an eleventh through via T313, a twelfth through via T314, and a second memory circuit (2^{nd} MEM CT) 410.

The ninth through via T311 may be electrically connected to the fifth micro bump B311. The tenth through via T312 may be electrically connected to the sixth micro bump B312. The eleventh through via T313 may be electrically connected to the seventh micro bump B313. The twelfth through via T314 may be electrically connected to the eighth micro bump B314. The ninth through via T311, the tenth through via T312, the eleventh through via T313, and the twelfth through via T314 may each be set as a common through via that penetrates the second core chip 121-2.

The second memory circuit 410 may receive the first output strobe signal IPDQS and the second output strobe signal IBPDQS through the tenth through via T312. The second memory circuit 410 may receive the first output strobe signal IPDQS and the second output strobe signal IBPDQS through the second signal path. The second memory circuit 410 may output the second data DO2 to the base chip 120 through the twelfth through via T314 in synchronization with the first output strobe signal IPDQS and the second output strobe signal IBPDQS. The second memory circuit 410 may output the second data DO2 to the base chip 120 through the fourth signal path in synchronization with the first output strobe signal IPDQS and the second output strobe signal IBPDQS.

The memory device 17 illustrated in FIG. 2 has been illustrated to include the base chip 120, the first core chip 121-1 and the second core chip 121-2, for convenience of description, but may be implemented with the base chip 120 and the plurality of core chips 121-1 to 121-L illustrated in FIG. 1.

FIG. 3 is a block diagram illustrating a construction of the base chip 120 according to an embodiment of the present disclosure. As illustrated in FIG. 3, the base chip 120 may include the first through via T111, the second through via T112, the third through via T113 and the fourth through via T114, the read control circuit 210, the base strobe signal generation circuit 220, and the data input and output circuit 230.

The first through via T111, the second through via T112, the third through via T113, and the fourth through via T114 may be disposed in the TSV region (TSV in FIG. 16).

The read control circuit 210 may be disposed in the peripheral region (PERI in FIG. 16). The read control circuit 210 may generate the even read signal RD-EV and the odd read signal RD-OD that are generated when the read command RD is input. The read control circuit 210 may generate the even read signal RD-EV that is generated when the first read command RD is input. The read control circuit 210 may generate the odd read signal RD-OD that is generated when the second read command RD is input. The first read command RD and the second read command RD may be set as the read command RD that is continuously input.

The base strobe signal generation circuit 220 may be disposed in the interface region (PHY in FIG. 16). The base strobe signal generation circuit 220 may generate the plurality of division clocks (IPS, QPS, PS-EV, IBPS, QBPS, and PS-OD in FIG. 7) each having the first frequency by dividing the frequencies of the even read signal RD-EV and the odd read signal RD-OD. The base strobe signal generation circuit 220 may generate the first output strobe signal IPDQS and the second output strobe signal IBPDQS each having the second frequency by synthesizing the plurality of division clocks (IPS, QPS, PS-EV, IBPS, QBPS, and PS-OD in FIG. 7). The base strobe signal generation circuit 220 may output the first output strobe signal IPDQS and the second output strobe signal IBPDQS to the first through via T111. The base strobe signal generation circuit 220 may output the first output strobe signal IPDQS and the second output strobe signal IBPDQS to the second through via T112.

The data input and output circuit 230 may be disposed in the peripheral region (PERI in FIG. 16). The data input and output circuit 230 may receive the first data DO1 from the first core chip 121-1 through the third through via T113. The data input and output circuit 230 may output the first data DO1 as the external data EDO in synchronization with the first output strobe signal IPDQS and the second output strobe signal IBPDQS. The data input and output circuit 230 may receive the second data DO2 from the second core chip 121-2 through the fourth through via T114. The data input and output circuit 230 may output the second data DO2 as the external data EDO in synchronization with the first output strobe signal IPDQS and the second output strobe signal IBPDQS.

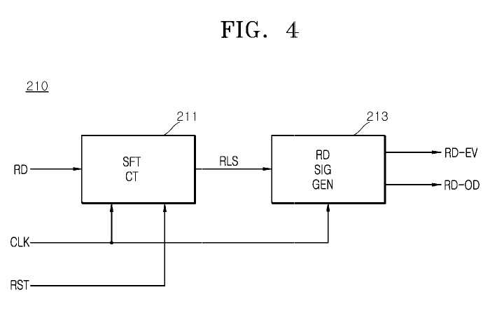

FIG. 4 is a block diagram illustrating a construction of the read control circuit 210 according to an embodiment of the present disclosure. As illustrated in FIG. 4, the read control circuit 210 may include a shifting circuit (SFT CT) 211 and a read signal generation circuit (RD SIG GEN) 213.

The shifting circuit 211 may generate a read latency signal RLS by shifting the read command RD in synchronization with a clock CLK. The shifting circuit 211 may generate the read latency signal RLS by delaying the read command RD by a read latency interval in synchronization with the clock CLK. The shifting circuit 211 may generate the read latency signal RLS that is disabled when the reset signal RST is input. The clock CLK may be set as a signal that is periodically toggled in order to synchronize operations of the base chip 120, the first core chip 121-1, and the second core chip 121-2. The reset signal RST may be set as a signal that is enabled in order to reset an operation of the memory device 17. The read latency interval may be set as a time interval in which data stored in the first memory circuit 310 and the second memory circuit 410 are output from timing at which the read command RD is input.

The read signal generation circuit 213 may generate the even read signal RD-EV and the odd read signal RD-OD that are generated based on the read latency signal RLS, in synchronization with the clock CLK. The read signal generation circuit 213 may generate the even read signal RD-EV that is generated based on the read latency signal RLS, in synchronization with the clock CLK. After generating the even read signal RD-EV, the read signal generation circuit 213 may generate the odd read signal RD-OD that is generated when the read latency signal RLS is input again, in synchronization with the clock CLK.

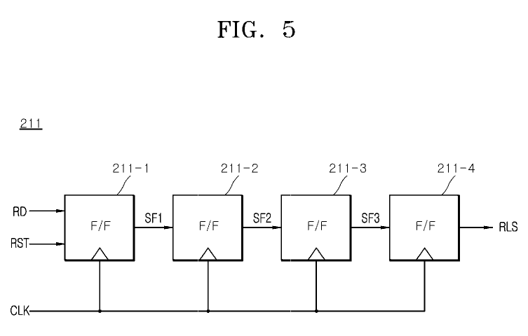

FIG. 5 is a block diagram illustrating a construction of the shifting circuit 211 according to an embodiment of the present disclosure. As illustrated in FIG. 5, the shifting circuit 211 may include flip-flops (F/F) 211-1, 211-2, 211-3, and 211-4.

The flip-flop 211-1 may generate a first shifting signal SF1 based on the read command RD in synchronization with the clock CLK. The flip-flop 211-1 may latch the read command RD when a pulse of the clock CLK is generated, and may output the latched read command RD as the first shifting signal SF1. The flip-flop 211-1 may latch the read command RD that is input at a logic high level when a pulse of the clock CLK is generated, and may output the latched read command RD as the first shifting signal SF1. The flip-flop 211-1 may generate the first shifting signal SF1 that is disabled to a logic low level when a pulse of the reset signal RST is generated.

The flip-flop 211-2 may generate a second shifting signal SF2 based on the first shifting signal SF1 in synchronization with the clock CLK. The flip-flop 211-2 may latch the first shifting signal SF1 when a pulse of the clock CLK is generated, and may output the latched first shifting signal SF1 as the second shifting signal SF2. The flip-flop 211-2 may latch the first shifting signal SF1 that is input at a logic high level when a pulse of the clock CLK is generated, and may output the latched first shifting signal SF1 as the second shifting signal SF2.

The flip-flop 211-3 may generate a third shifting signal SF3 based on the second shifting signal SF2 in synchronization with the clock CLK. The flip-flop 211-3 may latch the second shifting signal SF2 when a pulse of the clock CLK is generated, and may output the latched second shifting signal SF2 as the third shifting signal SF3. The flip-flop 211-3 may latch the second shifting signal SF2 that is input at a logic high level when a pulse of the clock CLK is generated, and may output the latched second shifting signal SF2 as the third shifting signal SF3.

The flip-flop 211-4 may generate the read latency signal RLS based on the third shifting signal SF3 in synchronization with the clock CLK. The flip-flop 211-4 may latch the third shifting signal SF3 when a pulse of the clock CLK is generated, and may output the latched third shifting signal SF3 as the read latency signal RLS. The flip-flop 211-4 may latch the third shifting signal SF3 that is input at a logic high level when a pulse of the clock CLK is generated, and may output the latched third shifting signal SF3 as the read latency signal RLS.

The shifting circuit 211 has been implemented with the four flip-flops 211-1, 211-2, 211-3, and 211-4, but may be implemented with various numbers of flip-flops that generate the read latency signal RLS by delaying the read command RD by a read latency interval.

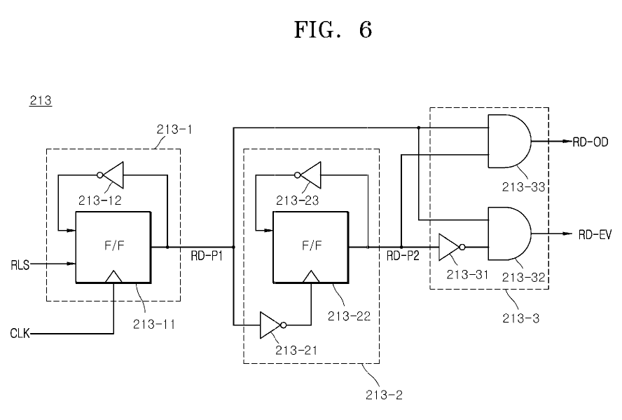

FIG. 6 is a diagram illustrating a construction of the read signal generation circuit 213 according to an embodiment of the present disclosure. As illustrated in FIG. 6, the read signal generation circuit 213 may include a first read pre-signal generation circuit 213-1, a second read pre-signal generation circuit 213-2, and a first logic circuit 213-3.

The first read pre-signal generation circuit 213-1 may be implemented with a flip-flop (F/F) 213-11 and an inverter 213-12. The flip-flop 213-11 may generate a first read pre-signal RD-P1 based on the read latency signal RLS in synchronization with the clock CLK. The flip-flop 213-11 may generate the first read pre-signal RD-P1 at a logic low level when the read latency signal RLS at a logic high level is input. The inverter 213-12 may output the first read pre-signal RD-P1 by inverting and buffering the first read pre-signal RD-P1. The flip-flop 213-11 may latch the output signal of the inverter 213-12 when a pulse of the clock CLK is generated, and may output the latched output signal of the latched inverter 213-12 as the first read pre-signal RD-P1. The first read pre-signal generation circuit 213-1 may generate the first read pre-signal RD-P1 that is enabled from a logic low level to a logic high level when the read latency signal RLS is input in synchronization with a rising edge of the clock CLK.

The second read pre-signal generation circuit 213-2 may be implemented with an inverter 213-21, a flip-flop (F/F) 213-22, and an inverter 213-23. The inverter 213-21 may output the first read pre-signal RD-P1 by inverting and buffering the first read pre-signal RD-P1. The flip-flop 213-22 may latch the output signal of the inverter 213-23 when the output signal of the inverter 213-21 is input at a logic high level, and may output the latched output signal of the inverter 213-23 as a second read pre-signal RD-P2. The inverter 213-23 may output the second read pre-signal RD-P2 by inverting and buffering the second read pre-signal RD-P2. The second read pre-signal generation circuit 213-2 may generate the second read pre-signal RD-P2 that is enabled from a logic low level to a logic high level in synchronization with a falling edge of the first read pre-signal RD-P1.

The first logic circuit 213-3 may be implemented with an inverter 213-31 and AND gates 213-32 and 213-33. The inverter 213-31 may output the second read pre-signal RD-P2 by inverting and buffering the second read pre-signal RD-P2. The AND gate 213-32 may generate the even read signal RD-EV by performing an AND operation on the first read pre-signal RD-P1 and the output signal of the inverter 213-31. The AND gate 213-33 may generate the odd read signal RD-OD by performing an AND operation on the first read pre-signal RD-P1 and the second read pre-signal RD-P2. The first logic circuit 213-3 may generate the even read signal RD-EV that is generated at a logic high level when the second read pre-signal RD-P2 is disabled to a logic low level during an interval in which the first read pre-signal RD-P1 is enabled to a logic high level. The first logic circuit 213-3 may generate the odd read signal RD-OD that is generated at a logic high level when the second read pre-signal RD-P2 is enabled to a logic high level during an interval in which the first read pre-signal RD-P1 is enabled to a logic high level.

FIG. 7 is a block diagram illustrating a construction of the base strobe signal generation circuit 220 according to an embodiment of the present disclosure. As illustrated in FIG. 7, the base strobe signal generation circuit 220 may include a signal synthesis circuit (SIG SUM) 221, a synchronization circuit (SYNC CT) 223, and a strobe signal generation circuit (DQS GEN) 225.

The signal synthesis circuit 221 may generate an even read synthesis signal RSUM-EV and an odd read synthesis signal RSUM-OD based on the even read signal RD-EV and the odd read signal RD-OD in synchronization with the clock CLK. The signal synthesis circuit 221 may generate the even read synthesis signal RSUM-EV and the odd read synthesis signal RSUM-OD by increasing the pulse widths of the even read signal RD-EV and the odd read signal RD-OD in synchronization with the clock CLK.

The synchronization circuit 223 may generate a first division clock IPS, a second division clock QPS, a third division clock PS-EV, a fourth division clock IBPS, a fifth division clock QBPS, and a sixth division clock PS-OD, based on the even read synthesis signal RSUM-EV and the odd read synthesis signal RSUM-OD in synchronization with the clock CLK. The synchronization circuit 223 may generate the first division clock IPS, the second division clock QPS, and the third division clock PS-EV each having the first frequency based on the even read synthesis signal RSUM-EV in synchronization with the clock CLK. The synchronization circuit 223 may generate the fourth division clock IBPS, the fifth division clock QBPS, and the sixth division clock PS-OD each having the first frequency based on the odd read synthesis signal RSUM-OD in synchronization with the clock CLK.

The strobe signal generation circuit 225 may generate the first output strobe signal IPDQS and the second output strobe signal IBPDQS, based on the first division clock IPS, the second division clock QPS, the third division clock PS-EV, the fourth division clock IBPS, the fifth division clock QBPS, and the sixth division clock PS-OD. The strobe signal generation circuit 225 may generate the first output strobe signal IPDQS and the second output strobe signal IBPDQS each having the second frequency, based on a combination of the logic levels of the first division clock IPS, the second division clock QPS, the third division clock PS-EV, the fourth division clock IBPS, the fifth division clock QBPS, and the sixth division clock PS-OD.

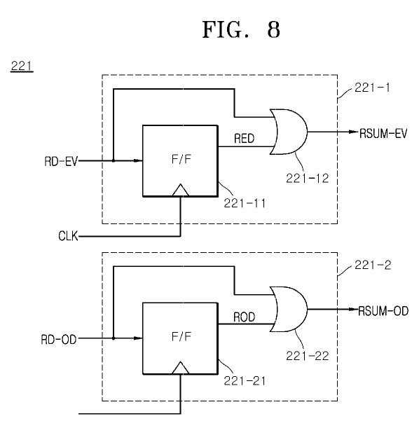

FIG. 8 is a block diagram illustrating a construction of the signal synthesis circuit 221 according to an embodiment of the present disclosure. As illustrated in FIG. 8, the signal synthesis circuit 221 may include an even read synthesis signal generation circuit 221-1 and an odd read synthesis signal generation circuit 221-2.

The even read synthesis signal generation circuit 221-1 may be implemented with a flip-flop (F/F) 221-11 and an OR gate 221-12. The flip-flop 221-11 may latch the even read signal RD-EV in synchronization with the clock CLK, and may output the latched even read signal RD-EV as an even read delay signal RED. The OR gate 221-12 may generate the even read synthesis signal RSUM-EV by performing an OP operation on the even read signal RD-EV and the even read delay signal RED. The even read synthesis signal generation circuit 221-1 may generate the even read synthesis signal RSUM-EV at a logic high level when any one of the even read signal RD-EV and the even read delay signal RED is generated at a logic high level.

The odd read synthesis signal generation circuit 221-2 may be implemented with a flip-flop (F/F) 221-21 and an OR gate 221-22. The flip-flop 221-21 may latch the odd read signal RD-OD in synchronization with the clock CLK, and may output the latched odd read signal RD-OD as an odd read delay signal ROD. The OR gate 221-22 may generate the odd read synthesis signal RSUM-OD by performing an OP operation on the odd read signal RD-OD and the odd read delay signal ROD. The odd read synthesis signal generation circuit 221-2 may generate the odd read synthesis signal RSUM-OD at a logic high level when any one of the odd read signal RD-OD and the odd read delay signal ROD is generated at a logic high level.

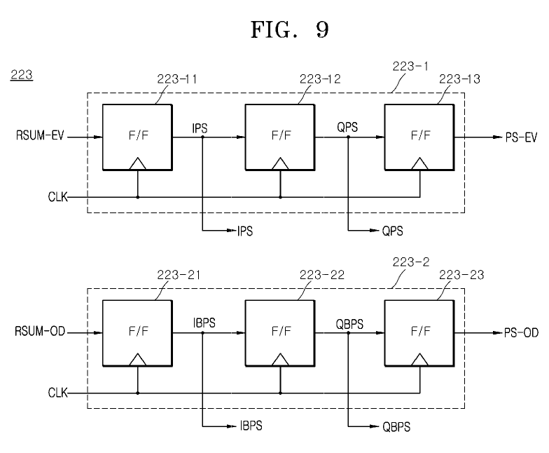

FIG. 9 is a block diagram illustrating a construction of the synchronization circuit 223 according to an embodiment of the present disclosure. As illustrated in FIG. 9, the synchronization circuit 223 may include a first division clock shifting circuit 223-1 and a second division clock shifting circuit 223-2.

The first division clock shifting circuit 223-1 may include flip-flops (F/F) 223-11, 223-12, and 223-13.

The flip-flop 223-11 may generate the first division clock IPS based on the even read synthesis signal RSUM-EV in synchronization with the clock CLK. The flip-flop 223-11 may latch the even read synthesis signal RSUM-EV when a pulse of the clock CLK is generated, and may output the latched even read synthesis signal RSUM-EV as the first division clock IPS. The flip-flop 223-11 may latch the even read synthesis signal RSUM-EV that is input at a logic high level when a pulse of the clock CLK is generated, and may output the latched even read synthesis signal RSUM-EV as the first division clock IPS having the first frequency.

The flip-flop 223-12 may generate the second division clock QPS based on the first division clock IPS in synchronization with the clock CLK. The flip-flop 223-11 may latch the first division clock IPS when a pulse of the clock CLK is generated, and may output the latched first division clock IPS as the second division clock QPS. The flip-flop 223-11 may latch the first division clock IPS that is input at a logic high level when a pulse of the clock CLK is generated, and may output the latched first division clock IPS the second division clock QPS having the first frequency.

The flip-flop 223-13 may generate the third division clock PS-EV based on the second division clock QPS in synchronization with the clock CLK. The flip-flop 223-13 may latch the second division clock QPS when a pulse of the clock CLK is generated, and may output the latched second division clock QPS as the third division clock PS-EV. The flip-flop 223-13 may latch the second division clock QPS that is input at a logic high level when a pulse of the clock CLK is generated, and may output the latched second division clock QPS as the third division clock PS-EV having the first frequency.

The second division clock shifting circuit 223-2 may include flip-flops (F/F) 223-21, 223-22, and 223-23.

The flip-flop 223-21 may generate the fourth division clock IBPS based on the odd read synthesis signal RSUM-OD in synchronization with the clock CLK. The flip-flop 223-21 may latch the odd read synthesis signal RSUM-OD when a pulse of the clock CLK is generated, and may output the latched odd read synthesis signal RSUM-OD as the fourth division clock IBPS. The flip-flop 223-21 may latch the odd read synthesis signal RSUM-OD that is input at a logic high level when a pulse of the clock CLK is generated, and may output the latched odd read synthesis signal RSUM-OD as the fourth division clock IBPS having the first frequency.

The flip-flop 223-22 may generate the fifth division clock QBPS based on the fourth division clock IBPS in synchronization with the clock CLK. The flip-flop 223-21 may latch the fourth division clock IBPS when a pulse of the clock CLK is generated, and may output the latched fourth division clock IBPS as the fifth division clock QBPS. The flip-flop 223-21 may latch the fourth division clock IBPS that is input at a logic high level when a pulse of the clock CLK is generated, and may output the latched first division clock IPS as the fifth division clock QBPS having the first frequency.

The flip-flop 223-23 may generate the sixth division clock PS-OD based on the fifth division clock QBPS in synchronization with the clock CLK. The flip-flop 223-23 may latch the fifth division clock QBPS when a pulse of the clock CLK is generated, and may output the latched fifth division clock QBPS as the sixth division clock PS-OD. The flip-flop 223-23 may latch the fifth division clock QBPS that is input at a logic high level when a pulse of the clock CLK is generated, and may output the latched fifth division clock QBPS as the sixth division clock PS-OD having the first frequency.

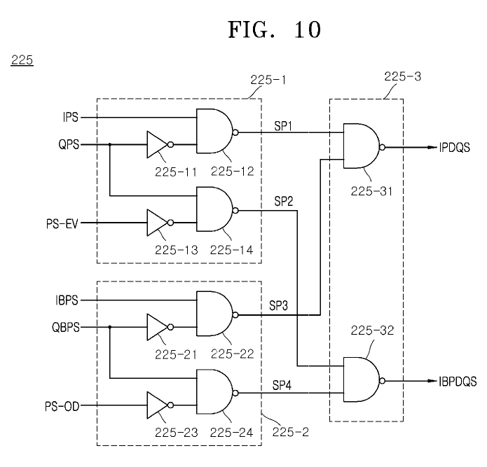

FIG. 10 is a circuit diagram illustrating a construction of the strobe signal generation circuit 225 according to an embodiment of the present disclosure. As illustrated in FIG. 10, the strobe signal generation circuit 225 may include a first pulse generation circuit 225-1, a second pulse generation circuit 225-2, and a second logic circuit 225-3.

The first pulse generation circuit 225-1 may be implemented with an inverter 225-11, a NAND gate 225-12, an inverter 225-13, and a NAND gate 225-14. The inverter 225-11 may output the second division clock QPS by inverting and buffering the second division clock QPS. The NAND gate 225-12 may generate a first synthesis pulse SP1 by performing a NAND operation on the first division clock IPS and the output signal of the inverter 225-11. The inverter 225-13 may output the third division clock PS-EV by inverting and buffering the third division clock PS-EV. The NAND gate 225-14 may generate a second synthesis pulse SP2 by performing a NAND operation on the second division clock QPS and the output signal of the inverter 225-13.

The first pulse generation circuit 225-1 may generate the first synthesis pulse SP1 at a logic low level, when the first division clock IPS is generated at a logic high level and the second division clock QPS is generated at a logic low level. The first pulse generation circuit 225-1 may generate a second synthesis pulse SP2 at a logic low level, when the second division clock QPS is generated at a logic high level and the third division clock PS-EV is generated at a logic low level.

The second pulse generation circuit 225-2 may be implemented with an inverter 225-21, a NAND gate 225-22, an inverter 225-23, and a NAND gate 225-24. The inverter 225-21 may output the fifth division clock QBPS by inverting and buffering the fifth division clock QBPS. The NAND gate 225-12 may generate a third synthesis pulse SP3 by performing a NAND operation on the fourth division clock IBPS and the output signal of the inverter 225-21. The inverter 225-23 may output the sixth division clock PS-OD by inverting and buffering the sixth division clock PS-OD. The NAND gate 225-24 may generate a fourth synthesis pulse SP4 by performing a NAND operation on the fifth division clock QBPS and the output signal of the inverter 225-23.

The second pulse generation circuit 225-2 may generate the third synthesis pulse SP3 at a logic low level, when the fourth division clock IBPS is generated at a logic high level and the fifth division clock QBPS is generated at a logic low level. The second pulse generation circuit 225-2 may generate the fourth synthesis pulse SP4 at a logic low level, when the fifth division clock QBPS is generated at a logic high level and the sixth division clock PS-OD is generated at a logic low level.

The second logic circuit 225-3 may include a NAND gate 225-31 and a NAND gate 225-32. The NAND gate 225-31 may generate the first output strobe signal IPDQS by performing a NAND operation on the first synthesis pulse SP1 and the third synthesis pulse SP3. The NAND gate 225-32 may generate the second output strobe signal IBPDQS by performing a NAND operation on the second synthesis pulse SP2 and the fourth synthesis pulse SP4.

The second logic circuit 225-3 may generate the first output strobe signal IPDQS that is generated at a logic high level when any one of the first synthesis pulse SP1 and the third synthesis pulse SP3 is generated at a logic low level. The second logic circuit 225-3 may generate the first output strobe signal IPDQS that is generated at a logic low level when both the first synthesis pulse SP1 and the third synthesis pulse SP3 are generated at a logic high level. The second logic circuit 225-3 may generate the second output strobe signal IBPDQS that is generated at a logic high level when any one of the second synthesis pulse SP2 and the fourth synthesis pulse SP4 is generated at a logic low level. The second logic circuit 225-3 may generate the second output strobe signal IBPDQS that is generated at a logic low level when both the second synthesis pulse SP2 and the fourth synthesis pulse SP4 are generated at a logic high level.

FIG. 11 is a block diagram illustrating a construction of the data input and output circuit 230 according to an embodiment of the present disclosure. As illustrated in FIG. 11, the data input and output circuit 230 may include a data control circuit (DATA CTR CT) 231 and a data output circuit (DATA OUT CT) 233.

The data control circuit 231 may generate a first output control signal DCTR and a second output control signal DBCTR, based on the first output strobe signal IPDQS and the second output strobe signal IBPDQS. The data control circuit 231 may generate the first output control signal DCTR and the second output control signal DBCTR each having a third frequency by adjusting the frequencies of the first output strobe signal IPDQS and the second output strobe signal IBPDQS each having the second frequency.

The data output circuit 233 may generate first to thirty-second bits EDO<1:32> of the external data, based on first to thirty-second bits DO1<1:32> of the first data and first to thirty-second bits DO2<1:32> of the second data in synchronization with the first output control signal DCTR and the second output control signal DBCTR. The data output circuit 233 may latch the first to thirty-second bits DO1<1:32> of the first data in synchronization with the first output control signal DCTR and the second output control signal DBCTR after the start of a read operation of the first core chip 121-1. The data output circuit 233 may output the latched first to thirty-second bits DO1<1:32> of the first data as the first to thirty-second bits EDO<1:32> of the external data. The data output circuit 233 may latch the first to thirty-second bits DO2<1:32> of the second data in synchronization with the first output control signal DCTR and the second output control signal DBCTR after the start of a read operation of the second core chip 121-2. The data output circuit 233 may output the latched first to thirty-second bits DO2<1:32> of the second data as the first to thirty-second bits EDO<1:32> of the external data. The first to thirty-second bits DO1<1:32> of the first data and the first to thirty-second bits DO2<1:32> of the second data may be input in series. The first to thirty-second bits EDO<1:32> of the external data may be output in parallel. The first to thirty-second bits EDO<1:32> of the external data may be output to the processor 19 through the wires of the interposer 15.

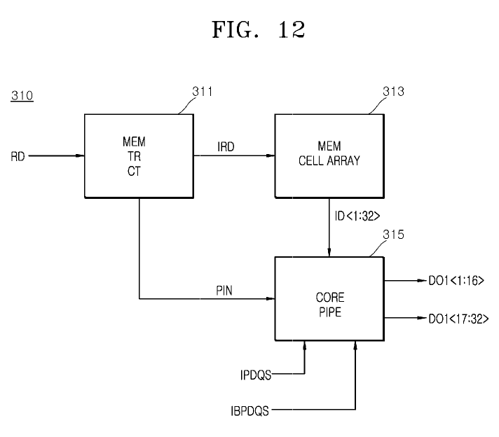

FIG. 12 is a block diagram illustrating a construction of the first memory circuit 310 according to an embodiment of the present disclosure. As illustrated in FIG. 12, the first memory circuit 310 may include a memory control circuit (MEM TR CT) 311, a memory cell array (MEM CELL ARRAY) 313, and a core pipe circuit (CORE PIPE) 315.

The memory control circuit 311 may generate an internal read signal IRD and an input control signal PIN based on the read command RD. The memory control circuit 311 may generate the internal read signal IRD and the input control signal PIN that are enabled when the read command RD is input. The internal read signal IRD has been set as a single signal, but may be set as a signal including an address that selects a memory cell of the memory cell array 313.

The memory cell array 313 may be implemented with a common memory cell array including a plurality of memory cell (not illustrated). The memory cell array 313 may output first to thirty-second bits ID<1:32> of internal data stored in the memory cell array 313 when the internal read signal IRD is enabled. The memory cell array 313 may output the first to thirty-second bits ID<1:32> of the stored internal data to a memory cell (not illustrated) that is selected by the internal read signal IRD.

The core pipe circuit 315 may be implemented with a common pipe circuit including a plurality of pipe lines. The core pipe circuit 315 may latch the first to thirty-second bits ID<1:32> of the internal data when the input control signal PIN is enabled. The core pipe circuit 315 may output the latched first to thirty-second bits ID<1:32> of the internal data as the first to thirty-second bits DO1<1:32> of the first data in synchronization with the first output strobe signal IPDQS and the second output strobe signal IBPDQS. The core pipe circuit 315 may output the latched first to sixteenth bits ID<1:16> of the internal data as the first to sixteenth bits DO1<1:16> of the first data in synchronization with the first output strobe signal IPDQS. The core pipe circuit 315 may output the latched seventeenth to thirty-second bits ID<17:32> of the internal data as the seventeenth to thirty-second bits DO1<17:32> of the first data in synchronization with the second output strobe signal IBPDQS.

The second memory circuit 410 illustrated in FIG. 2 has the same configuration as the first memory circuit 310 and performs the same operation as the first memory circuit 310, except signal paths along which the first output strobe signal IPDQS and the second output strobe signal IBPDQS are input and a signal path along which the second data DO2 is output, and a detailed description thereof is omitted.

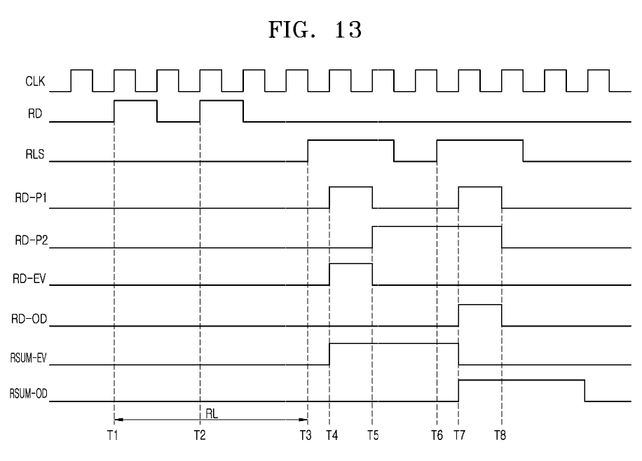

FIGS. 13 to 15 are timing diagrams for describing read operations of the memory device 17 according to an embodiment of the present disclosure.

An operation of generating, by the base chip 120, the output strobe signals IPDQS and IBPDQS after the start of a read operation of the memory device 17 and providing the first core chip 121-1 with the output strobe signals IPDQS and IBPDQS, and outputting, by the first core chip 121-1, the first data DO1<1:32> in synchronization with the output strobe signals IPDQS and IBPDQS according to an embodiment of the present disclosure is described as an example as follows with reference to FIGS. 13 to 15.

First, an operation of generating, by the read control circuit 210, the even read signal RD-EV and the odd read signal RD-OD based on the first and the second read commands RD that are continuously input is described with reference to FIG. 13.

At timing T1, the first read command RD is input. At timing T2, the second read command RD is continuously input.

At timing T3, the shifting circuit 211 generates the read latency signal RLS by delaying the first read command RD that is input at timing T1 by the interval of read latency (RL) in synchronization with the clock CLK.

At timing T4, the first read pre-signal generation circuit 213-1 of the read signal generation circuit 213 generates the first read pre-signal RD-P1 that is enabled from a logic low level to a logic high level when the read latency signal RLS is input in synchronization with a rising edge of the clock CLK.

The first logic circuit 213-3 of the read signal generation circuit 213 generates the even read signal RD-EV at a logic high level by the first read pre-signal RD-P1 at the logic high level and the second read pre-signal RD-P2 at a logic low level.

The signal synthesis circuit 221 of the base strobe signal generation circuit 220 generates the even read synthesis signal RSUM-EV at a logic high level by increasing the pulse width of the even read signal RD-EV at a logic high level in synchronization with the clock CLK.

At timing T5, the first read pre-signal generation circuit 213-1 of the read signal generation circuit 213 generates the first read pre-signal RD-P1 that is disabled from the logic high level to a logic low level in synchronization with a rising edge of the clock CLK.

The second read pre-signal generation circuit 213-2 of the read signal generation circuit 213 generates the second read pre-signal RD-P2 that is enabled from the logic low level to a logic high level in synchronization with a falling edge of the first read pre-signal RD-P1.

The first logic circuit 213-3 of the read signal generation circuit 213 generates the even read signal RD-EV at a logic low level by the first read pre-signal RD-P1 at the logic low level and the second read pre-signal RD-P2 at the logic high level.

At timing T6, the shifting circuit 211 generates the read latency signal RLS by delaying the first read command RD that is input at timing T2 by the interval of the read latency RL in synchronization with the clock CLK.

At timing T7, the first read pre-signal generation circuit 213-1 of the read signal generation circuit 213 generates the first read pre-signal RD-P1 that is enabled from the logic low level to a logic high level when the read latency signal RLS is input in synchronization with a rising edge of the clock CLK.

The first logic circuit 213-3 of the read signal generation circuit 213 generates the odd read signal RD-OD at a logic high level by the first read pre-signal RD-P1 at the logic high level and the second read pre-signal RD-P2 at the logic high level.

The signal synthesis circuit 221 of the base strobe signal generation circuit 220 generates the odd read synthesis signal RSUM-OD at a logic high level by increasing the pulse width of the odd read signal RD-OD at a logic high level in synchronization with the clock CLK. At this time, the odd read synthesis signal RSUM-OD is generating to have the first frequency.

At timing T8, the first read pre-signal generation circuit 213-1 of the read signal generation circuit 213 generates the first read pre-signal RD-P1 that is disabled from the logic high level to a logic low level in synchronization with a rising edge of the clock CLK.

The second read pre-signal generation circuit 213-2 of the read signal generation circuit 213 generates the second read pre-signal RD-P2 that is disabled from the logic high level to a logic low level in synchronization with a falling edge of the first read pre-signal RD-P1.

The first logic circuit 213-3 of the read signal generation circuit 213 generates the odd read signal RD-OD at a logic low level by the first read pre-signal RD-P1 at the logic low level and the second read pre-signal RD-P2 at the logic low level.

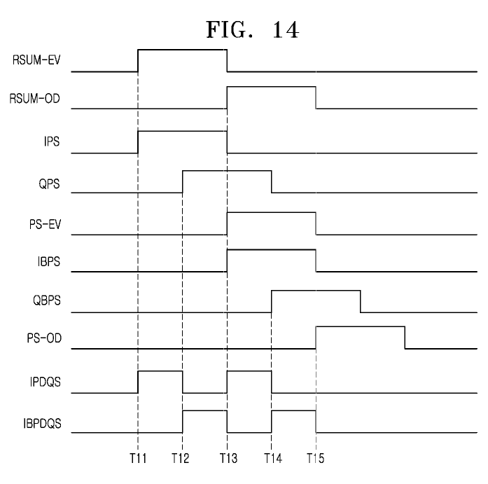

Hereinafter, an operation of generating, by the base strobe signal generation circuit 220, the first to sixth division clocks IPS, QPS, PS-EV, IBPS, QBPS, and PS-OD each having the first frequency based on the even read signal RD-EV and the odd read signal RD-OD and generating the first output strobe signal IPDQS and the second output strobe signal IBPDQS each having the second frequency by synthesizing the first to sixth division clocks IPS, QPS, PS-EV, IBPS, QBPS, and PS-OD is described with reference to FIG. 14.

At timing T11, the synchronization circuit 223 of the base strobe signal generation circuit 220 latches the even read synthesis signal RSUM-EV when a pulse of the clock CLK is generated, and outputs the latched even read synthesis signal RSUM-EV as the first division clock IPS. The first division clock IPS is generated to have the first frequency.

The even read synthesis signal RSUM-EV is generated as a signal that is obtained by dividing the clock CLK by four because the first frequency is set as a 1/4 frequency of the clock CLK. The first frequency is set as the 1/4 frequency of the clock CLK, but may be variously set as a 1/8 frequency or 1/16 frequency of the clock CLK according to an embodiment.

The strobe signal generation circuit 225 of the base strobe signal generation circuit 220 generates the first output strobe signal IPDQS at a logic high level by the first division clock IPS at a logic high level and the second division clock QPS at a logic low level.

Timing T11 is set as the same timing as timing T4 illustrated in FIG. 13.

At timing T12, the synchronization circuit 223 of the base strobe signal generation circuit 220 latches the first division clock IPS when a pulse of the clock CLK, and outputs the latched first division clock IPS as the second division clock QPS. The second division clock QPS is generated to have the first frequency.

The strobe signal generation circuit 225 of the base strobe signal generation circuit 220 generates the first output strobe signal IPDQS at a logic low level by the first division clock IPS at the logic high level and the second division clock QPS at the logic high level. That is, the first output strobe signal IPDQS is generated to have the second frequency.

The first output strobe signal IPDQS is generated as a signal that is obtained by dividing the clock CLK by 2 because the second frequency is set as a 1/2 frequency of the clock CLK. The second frequency is set as the 1/2 frequency of the clock CLK, but may be variously set as a 1/4 frequency or 1/8 frequency of the clock CLK according to an embodiment.

The strobe signal generation circuit 225 of the base strobe signal generation circuit 220 generates the second output strobe signal IBPDQS at a logic high level by the second division clock QPS at a logic high level and the third division clock PS-EV at a logic low level.

At timing T13, the synchronization circuit 223 of the base strobe signal generation circuit 220 latches the second division clock QPS when a pulse of the clock CLK is generated, and outputs the latched second division clock QPS as the third division clock PS-EV. The third division clock PS-EV is generated to have the first frequency.

The synchronization circuit 223 of the base strobe signal generation circuit 220 latches the odd read synthesis signal RSUM-OD when a pulse of the clock CLK is generated, and outputs the latched odd read synthesis signal RSUM-OD as the fourth division clock IBPS. The fourth division clock IBPS is generated to have the first frequency.

The strobe signal generation circuit 225 of the base strobe signal generation circuit 220 generates the first output strobe signal IPDQS at a logic high level by the fourth division clock IBPS at a logic high level and the fifth division clock QBPS at a logic low level.

The strobe signal generation circuit 225 of the base strobe signal generation circuit 220 generates the second output strobe signal IBPDQS at a logic low level by the third division clock PS-EV at a logic high level and the fifth division clock QBPS at the logic low level. That is, the second output strobe signal IBPDQS is generated to have the second frequency.

Timing T13 is set as the same timing as timing T7 illustrated in FIG. 13.

At timing T14, the synchronization circuit 223 of the base strobe signal generation circuit 220 latches the fourth division clock IBPS when a pulse of the clock CLK is generated, and outputs the latched fourth division clock IBPS as the fifth division clock QBPS. The fifth division clock QBPS is generated to have the first frequency.

The strobe signal generation circuit 225 of the base strobe signal generation circuit 220 generates the second output strobe signal IBPDQS at a logic high level by the fifth division clock QBPS at a logic high level and the sixth division clock PS-OD at a logic low level.

At timing T15, the synchronization circuit 223 of the base strobe signal generation circuit 220 latches the fifth division clock QBPS when a pulse of the clock CLK is generated, and outputs the latched fifth division clock QBPS as the sixth division clock PS-OD. The sixth division clock PS-OD is generated to have the first frequency.

The strobe signal generation circuit 225 of the base strobe signal generation circuit 220 generates the second output strobe signal IBPDQS at a logic low level by the sixth division clock PS-OD at a logic high level and the second division clock QPS at a logic low level. That is, the second output strobe signal IBPDQS is generated to have the second frequency.

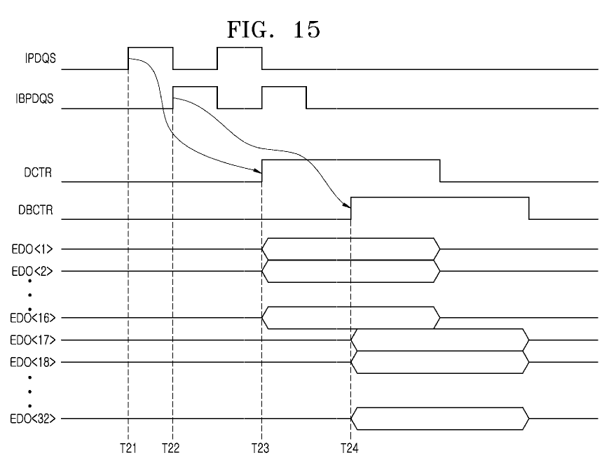

Hereinafter, an operation of outputting, by the data input and output circuit 230, the first to thirty-second bits DO1<1:32> of the first data that are input from the first core chip 121-1 as the first to thirty-second bits EDO<1:32> of the external data in synchronization with the first output strobe signal IPDQS and the second output strobe signal IBPDQS is described with reference to FIG. 15.

At timing T21, the first output strobe signal IPDQS is input. At timing T22, the second output strobe signal IBPDQS is input. Timing T21 is set as the same timing as timing T11 illustrated in FIG. 14. Timing T22 is set as the same timing as timing T12 illustrated in FIG. 14.

At timing T23, the data control circuit 231 of the data input and output circuit 230 generates the first output control signal DCTR having the third frequency by adjusting the frequency of the first output strobe signal having the second frequency IPDQS, which is input at timing T21. The third frequency is set as half the second frequency.

The data output circuit 233 of the data input and output circuit 230 latches the first to sixteenth bits DO1<1:16> of the first data in synchronization with the first output control signal DCTR after the start of a read operation of the first core chip 121-1. The data output circuit 233 outputs the latched first to sixteenth bits DO1<1:16> of the first data as the first to sixteenth bits EDO<1:16> of the external data. The first to sixteenth bits EDO<1:16> of the external data are output in parallel.

At timing T24, the data control circuit 231 of the data input and output circuit 230 generates the second output control signal DBCTR having the third frequency by adjusting the frequency of the second output strobe signal IBPDQS having the second frequency, which is input at timing T22.

The data output circuit 233 of the data input and output circuit 230 latches the seventeenth to thirty-second bits DO1<17:32> of the first data in synchronization with the second output strobe signal IBPDQS after the start of a read operation of the first core chip 121-1. The data output circuit 233 outputs the latched seventeenth to thirty-second bits DO1<17:32> of the first data as the seventeenth to thirty-second bits EDO<17:32> of the external data. The seventeenth to thirty-second bits EDO<17:32> of the external data are output in parallel.

As described above, the memory device 17 of the memory system 1 according to an embodiment of the present disclosure may input and output data by generating the output strobe signals IPDQS and IBPDQS by dividing the frequencies of the output strobe signals IPDQS and IBPDQS in the interface region PHY of the base chip 120 having long loading and providing the generated output strobe signals IPDQS and IBPDQS to the plurality of core chips 121-1 to 121-L through a signal path. In an embodiment, the memory device 17 of the memory system 1 can prevent or mitigate the degradation of the output strobe signals IPDQS and IBPDQS attributable to long loading, by generating the output strobe signals IPDQS and IBPDQS by dividing the frequencies of the output strobe signals IPDQS and IBPDQS in the interface region PHY of the base chip 120 having long loading and providing the generated output strobe signals IPDQS and IBPDQS to the plurality of core chips 121-1 to 121-L.

FIG. 16 is a diagram for describing location at which the peripheral region PERI, the interface region PHY, and the through via region TSV included in the base chip 120 are disposed according to an embodiment of the present disclosure.

The through via region TSV may be disposed on the top side TOP of the base chip 120 in a Y axis.

The through via region TSV may be set as a region including a plurality of through vias. The through via region TSV may include the first through via T111, the second through via T112, the third through via T113, and the fourth through via T114.

The interface region PHY may be disposed in a first direction DIR1 on the basis of the through via region TSV. The first direction DIR1 may be set as a direction downward from the top side TOP.

The interface region PHY may include an internal wire having long loading. The interface region PHY may include the base strobe signal generation circuit 220. The base strobe signal generation circuit 220 may generate the first to sixth division clocks (IPS, QPS, PS-EV, IBPS, QBPS, and PS-OD in FIG. 7) each having the first frequency by dividing the frequencies of the even read signal RD-EV and the odd read signal RD-OD through the internal wire having long loading. The base strobe signal generation circuit 220 may generate the first output strobe signal IPDQS and the second output strobe signal IBPDQS each having the second frequency by synthesizing the first to sixth division clocks (IPS, QPS, PS-EV, IBPS, QBPS, and PS-OD in FIG. 7). The base strobe signal generation circuit 220 may output the first output strobe signal IPDQS and the second output strobe signal IBPDQS to the first through via T111 and the second through via T112 included in the through via region TSV through the internal wire having long loading.

The peripheral region PERI may be disposed in the first direction DIR1 from the interface region PHY.

The peripheral region PERI may be set as a region including circuits that control operations of the plurality of core chips 121-1 to 121-L.

The peripheral region PERI may include the read control circuit 210 and the data input and output circuit 230.

The read control circuit 210 may generate the even read signal RD-EV and the odd read signal RD-OD that are generated when the read command RD is input. The read control circuit 210 may output the even read signal RD-EV and the odd read signal RD-OD to the base strobe signal generation circuit 220 included in the interface region PHY.

The data input and output circuit 230 may receive the first data DO1 from the first core chip 121-1 through the third through via T113. The data input and output circuit 230 may output the first data DO1 as the external data EDO in synchronization with the first output strobe signal IPDQS and the second output strobe signal IBPDQS. The data input and output circuit 230 may receive the second data DO2 from the second core chip 121-2 through the fourth through via T114. The data input and output circuit 230 may output the second data DO2 as the external data EDO in synchronization with the first output strobe signal IPDQS and the second output strobe signal IBPDQS.

According to an embodiment, the through via region TSV may be disposed on the bottom side BOTTOM of the base chip 120 in the Y axis. If the through via region TSV is disposed on the bottom side BOTTOM of the base chip 120 in the Y axis, the through via region TSV, the interface region PHY and the peripheral region PERI may be sequentially disposed in a second direction DIR2 on the basis of the through via region TSV. The second direction DIR2 may be set as a direction upward from the bottom side BOTTOM.

According to an embodiment, the through via region TSV may be disposed in on the left side LEFT of the base chip 120 in an X axis. If the through via region TSV is disposed on the left side LEFT of the base chip 120 in the X axis, the interface region PHY and the peripheral region PERI may be sequentially disposed in a third direction DIR3 on the basis of the through via region TSV. The third direction DIR3 may be set as a direction rightward from the left side LEFT.

According to an embodiment, the through via region TSV may be disposed on the right side RIGHT of the base chip 120 in the X axis. If the through via region TSV is disposed on the right side RIGHT of the base chip 120 in the X axis, the interface region PHY and the peripheral region PERI may be sequentially disposed in a fourth direction DIR4 on the basis of the through via region TSV. The fourth direction DIR4 may be set as a direction leftward from the right side RIGHT.

Locations at which the through via region TSV, the interface region PHY, and the peripheral region PERI are disposed may be variously disposed according to an embodiment.

As described above, the memory device 17 of the memory system 1 according to an embodiment of the present disclosure may input and output data by generating the output strobe signals IPDQS and IBPDQS by dividing the frequencies of the output strobe signals IPDQS and IBPDQS in the interface region PHY of the base chip 120 having long loading and providing the generated output strobe signals IPDQS and IBPDQS to the plurality of core chips 121-1 to 121-L through a signal path. The memory device 17 of the memory system 1 can prevent or mitigate the degradation of the output strobe signals IPDQS and IBPDQS attributable to long loading by generating the output strobe signals IPDQS and IBPDQS by dividing the frequencies of the output strobe signals IPDQS and IBPDQS in the interface region PHY of the base chip 120 having long loading and providing the generated the output strobe signals IPDQS and IBPDQS to the plurality of core chips 121-1 to 121-L.

What is claimed is:

1. A memory device comprising:
a base chip configured to generate a plurality of division clocks each comprising a first frequency by dividing frequencies of an even read signal and an odd read signal generated based on a read command, configured to generate first and second output strobe signals each comprising a second frequency by synthesizing the plurality of division clocks, and configured to output the first and second output strobe signals through a first signal path and second signal path, respectively; and
a core chip vertically stacked on the base chip through a portion of the first and second signal paths located between the core chip and the base chip, the core chip spaced apart from the base chip with the portions of the first and second signal paths, and the core chip configured to output data to the base chip through a third signal path and a fourth signal path in synchronization with the first and second output strobe signals.

2. The memory device of claim 1, wherein:
the first frequency is 1/N of the second frequency, and
the N is a positive integer.

3. The memory device of claim 1, wherein the plurality of division clocks each comprising the first frequency is generated in an interface region.

4. The memory device of claim 3, wherein loading of the interface region in which the plurality of division clocks each comprising the first frequency is transmitted is longer than loading of the signal path along which the first and second output strobe signals each comprising the second frequency are transmitted.

5. The memory device of claim 1, wherein the base chip comprises:
a read control circuit configured to generate the even read signal that is generated when the read command is input and configured to generate the odd read signal that is generated when the read command is input again; and
a base strobe signal generation circuit configured to generate the plurality of division clocks each comprising the first frequency by dividing the frequencies of the even read signal and the odd read signal, configured to generate the first and second output strobe signals each comprising the second frequency by synthesizing the plurality of division clocks, and configured to output the first and second output strobe signals through the signal path.

6. The memory device of claim 5, wherein:
the read control circuit is disposed in a peripheral region,
the base strobe signal generation circuit is disposed in an interface region, and
the signal path is disposed in a through via region.

7. The memory device of claim 5, wherein the read control circuit comprises:
a shifting circuit configured to generate a read latency signal by delaying the read command by an interval of read latency in synchronization with a clock; and
a read signal generation circuit configured to generate the even read signal that is generated based on the read latency signal in synchronization with the clock and configured to generate the odd read signal when the read latency signal is input again.

8. The memory device of claim 7, wherein the read signal generation circuit comprises:
a first read pre-signal generation circuit configured to generate a first read pre-signal that is enabled in synchronization with the clock after the read latency signal is input;
a second read pre-signal generation circuit configured to generate a second read pre-signal that is toggled in synchronization with the first read pre-signal; and
a first logic circuit configured to generate the even read signal that is generated when the second read pre-signal during an interval in that the first read pre-signal is enabled and configured to generate the odd read signal that is generated when the second read pre-signal is enabled during an interval in which the first read pre-signal is enabled.

9. The memory device of claim 5, wherein the base strobe signal generation circuit comprises:
a signal synthesis circuit configured to generate an even read synthesis signal and an odd read synthesis signal by increasing pulse widths of the even read signal and the odd read signal in synchronization with a clock;
a synchronization circuit configured to generate first, second, and third division clocks each comprising the first frequency based on the even read synthesis signal in synchronization with the clock and configured to generate fourth, fifth, and sixth division clocks each comprising the first frequency based on the odd read synthesis signal in synchronization with the clock; and
a strobe signal generation circuit configured to generate the first and second output strobe signals based on a combination of logic levels of the first to sixth division clocks and configured to output the first and second output strobe signals to the first and second signal paths.

10. The memory device of claim 9, wherein the signal synthesis circuit comprises:
an even read synthesis signal generation circuit configured to generate the even read synthesis signal by increasing the pulse width of the even read signal in synchronization with the clock; and
an odd read synthesis signal generation circuit configured to generate the odd read synthesis signal by increasing the pulse width of the odd read signal in synchronization with the clock.

11. The memory device of claim 9, wherein the synchronization circuit comprises:
a first division clock shifting circuit configured to sequentially generate the first, second, and third division clocks each comprising the first frequency by shifting the even read synthesis signal in synchronization with the clock; and
a second division clock shifting circuit configured to sequentially generate the fourth, fifth, and sixth division clocks comprising the first frequency by shifting the odd read synthesis signal in synchronization with the clock.

12. The memory device of claim 9, wherein the strobe signal generation circuit comprises:
a first pulse generation circuit configured to generate first and second synthesis pulses based on a combination of the logic levels of the first, second, and third division clocks;
a second pulse generation circuit configured to generate third and fourth synthesis pulses based on a combination of the logic levels of the fourth, fifth, and sixth division clocks; and
a second logic circuit configured to generates the first output strobe signal that is generated when the first synthesis pulse and the third synthesis pulse are generated and to output the first output strobe signal to the first signal path and configured to generate the second output strobe signal that is generated when the second synthesis pulse and the third synthesis pulse are generate and to output the second output strobe signal to the second signal path.

13. The memory device of claim 1, wherein the core chip comprises:
a memory control circuit configured to generate an internal read signal and an input control signal that are enabled when the read command is input;
a memory cell array configured to output internal data stored in the memory cell array when the internal read signal is enabled; and
a core pipe circuit configured to latch the internal data when the input control signal is enabled and configured to output, as the data, the internal data latched in synchronization with the first and second output strobe signals.

14. A memory device comprising:
a base chip configured to generate an even read signal that is generated based on a first read command and an odd read signal that is generated based on a second read command, configured to generate first, second, and third division clocks each comprising a first frequency by dividing a frequency of the even read signal, configured to generate fourth, fifth, and sixth division clocks each comprising the first frequency by dividing a frequency of the odd read signal, configured to generate a first output strobe signal comprising the second frequency by synthesizing the first to third division clocks, and configured to generate a second output strobe signal comprising the second frequency by synthesizing the fourth to sixth division clocks;
a first core chip configured to output first data to the base chip in synchronization with the first and second output strobe signals; and
a second core chip configured to output second data to the base chip in synchronization with the first and second output strobe signals.

15. The memory device of claim 14, wherein the first read command and the second read command are sequentially input.

16. The memory device of claim 14, wherein:
the first core chip is vertically stacked on the base chip,
the second core chip is vertically stacked on the first core chip,
the first core chip receives the first and second output strobe signals through a first signal path and a second signal path, respectively, and
the second core chip receives the first and second output strobe signals through the first signal path and the second signal path, respectively.

17. The memory device of claim 14, wherein:
the first frequency is 1/N of the second frequency, and
the N is a positive integer.

18. The memory device of claim 14, wherein the first to sixth division clocks each comprising the first frequency is generated in an interface region.

19. The memory device of claim 14, wherein the base chip comprises:
a read control circuit configured to generate the even read signal that is generated when the first read command is input and configured to generate the odd read signal that is generated when the second read command is input; and
a base strobe signal generation circuit configured to generate the first to third division clocks each comprising the first frequency by dividing the frequency of the even read signal, configured to generate the first output strobe signal comprising the second frequency by synthesizing the first to third division clocks, configured to generate the fourth to sixth division clocks each comprising the first frequency by dividing the frequency of the odd read signal, and configured to generate the second output strobe signal comprising the second frequency by synthesizing the fourth to sixth division clocks.

20. The memory device of claim 19, wherein:
the read control circuit is disposed in a peripheral region, and
the strobe signal generation circuit is disposed in an interface region.

21. The memory device of claim 19, wherein the read control circuit comprises:
a shifting circuit configured to generate a first read latency signal by delaying the first read command by an interval of read latency in synchronization with a clock and configured to generate a second the read latency signal by delaying the second read command by the interval of the read latency in synchronization with the clock; and
a read signal generation circuit configured to generate the even read signal that is generated based on the first read latency signal in synchronization with the clock and configured to generate the odd read signal that is generated when the second read latency signal is input.

22. The memory device of claim 19, wherein the base strobe signal generation circuit comprises:
a signal synthesis circuit configured to generate an even read synthesis signal and an odd read synthesis signal by increasing pulse widths of the even read signal and the odd read signal in synchronization with a clock;
a synchronization circuit configured to generate the first to third division clocks each comprising the first frequency based on the even read synthesis signal in synchronization with the clock and configured to generate the fourth to sixth division clocks each comprising the first frequency based on the odd read synthesis signal in synchronization with the clock; and
a strobe signal generation circuit configured to generate the first and second output strobe signals based on a combination of logic levels of the first to sixth division clocks.

23. The memory device of claim 22, wherein the signal synthesis circuit comprises:
an even read synthesis signal generation circuit configured to generate the even read synthesis signal by increasing a pulse width of the even read signal in synchronization with the clock; and
an odd read synthesis signal generation circuit configured to generate the odd read synthesis signal by increasing a pulse width of the odd read signal in synchronization with the clock.

24. The memory device of claim 22, wherein the synchronization circuit comprises:
a first division clock shifting circuit configured to sequentially generate the first to third division clocks each comprising the first frequency by shifting the even read synthesis signal in synchronization with the clock; and
a second division clock shifting circuit configured to sequentially generate the fourth to sixth division clocks each comprising the first frequency by shifting the odd read synthesis signal in synchronization with the clock.

25. The memory device of claim 22, wherein the strobe signal generation circuit comprises:
a first pulse generation circuit configured to generate first and second synthesis pulses based on a combination of the logic levels of the first to third division clocks;
a second pulse generation circuit configured to generate third and fourth synthesis pulses based on a combination of the logic levels of the fourth to sixth division clocks; and
a logic circuit configured to generate the first output strobe signal that is generated when the first synthesis pulse and the third synthesis pulse are generated and to output the first output strobe signal to a first signal path and configured to generate the second output strobe signal that is generated when the second synthesis pulse and the third synthesis pulse are generated and to output the second output strobe signal to the second signal path.

26. The memory device of claim 14, wherein the first core chip comprises a first memory circuit configured to receive the first and second output strobe signals through a first signal path and a second signal path and configured to output the first data to the base chip through a third signal path and a fourth signal path in synchronization with the first and second output strobe signals.

27. The memory device of claim 26, wherein the first memory circuit comprises:
a first memory control circuit configured to generate a first internal read signal and a first input control signal that are enabled when the first and second read commands are input;
a first memory cell array configured to output first internal data stored in the first memory cell array when the first internal read signal is enabled; and
a first core pipe circuit configured to receive the first and second output strobe signals through the first and second signal paths, configured to latch the first internal data when the first input control signal is enabled, and configured to output, as the first data, the first internal data that are latched in synchronization with the first and second output strobe signals through the third and fourth signal paths.

28. The memory device of claim 14, wherein the second core chip comprises a second memory circuit configured to receive the first and second output strobe signals through a first signal path and a second signal path and configured to output the second data to the base chip through a third signal path and a fourth signal path in synchronization with the first and second output strobe signals.

29. The memory device of claim 28, wherein the second memory circuit comprises:
a second memory control circuit configured to generate a second internal read signal and a second input control signal that are enabled when the first and second read commands are input;
a second memory cell array configured to output second internal data stored in the second memory cell array when the second internal read signal is enabled; and
a second core pipe circuit configured to receive the first and second output strobe signals through the first and second signal paths, configured to latch the second internal data when the second input control signal is enabled, and configured to output, as the second data, the second internal data that are latched in synchronization with the first and second output strobe signals through the third and fourth signal paths.
